(19) United States
(12) Patent Application Publication
(10) Pub. No.: US 2020/0075454 A1
(43) Pub. Date: Mar. 5, 2020

(54) Switching Device for Switching High Voltages for Cable Testing via the Application of High Voltage to a Test Cable and Discharge of the Test Cable

(71) Applicant: Hagenuk KMT Kabelmesstechnik GmbH, Radeburg (DE)

(72) Inventors: Sven Scheuschner, Radeburg (DE); Melanie Gründel, Radeburg (DE)

(21) Appl. No.: 16/550,331

(22) Filed: Aug. 26, 2019

(30) Foreign Application Priority Data
Aug. 29, 2018 (DE) 102018121048.5

(51) Int. Cl. H01L 23/367; H01L 29/74; H01L 29/739; H01L 23/50

(52) U.S. Cl. CPC H01L 23/3677; H01L 23/50; H01L 29/7393; H01L 29/74

(57) ABSTRACT

Switching devices for switching high voltages for cable testing by applying high voltage to a cable test sample and for discharging the cable test sample, wherein at least one device for switching a high voltage is connected to a negative high voltage source, and at least one identically embodied device for switching a high voltage is connected to a positive high voltage source. Said switching devices are distinguished in particular in that an increased voltage can be switched with a semiconductor switch. For this purpose, at least one electrically conductive heat sink having at least one printed circuit board with at least one semiconductor switch is arranged in an electrically insulated manner in a housing. The printed circuit board is a thermally conductive insulator between the semiconductor switch and the heat sink, to which and/or through which flows a coolant.

### CROSS REFERENCE TO RELATED APPLICATIONS

This application claims the priority of DE 102018121048.5 filed on 2018 Aug. 29; this application is incorporated by reference herein in its entirety.

### BACKGROUND

The invention relates to switching devices for switching high voltages for cable testing by applying high voltage to a cable test sample and for discharging the cable test sample, wherein at least one device for switching a high voltage is connected to a negative high voltage source, and at least one identically embodied device for switching a high voltage is connected to a positive high voltage source.

The power loss of semiconductor switches that occurs in devices for switching high voltages must be dissipated, since otherwise the semiconductor switches are destroyed. For this purpose, known heat sinks are used that conduct the heat resulting from the power loss away and give it off into the surroundings. Such a passive cooling can also be designed as active cooling, wherein a media flow is used on and/or in the heat sink. Air and water can be used as heat transfer media and thus as cooling media. The known heatsinks used to this end are in particular made of a metal such as aluminium. To increase the cooling surface, as is known these can have structures, such as fins, for example.

Document WO 99/39 428 A1 (AU 2 144 699 A) discloses a power converter with insulated gate bipolar transistors (IGBT) in the form of at least one IGBT module, wherein the power converter is provided as an inverter for variable speed control of synchronous or asynchronous machines. An IGBT module has a plurality of IGBTs arranged on a base. Furthermore, there is a module insulation that is a component of the IGBT module. These IGBT modules are attached to the cooling unit. Outside the IGBT module, additional insulation is provided between (cooling) fins and the cooling unit. The power converter has the cooling unit, which is connected via the insulation to the cooling fins, which are at the potential 0. These cooling fins are used for heat dissipation. Furthermore, the base and the insulation are present between the IGBTs. Thus, the power converter comprises the IGBT modules as power dissipation generator, a module insulation as a first thermal resistor, a first cooling component as a heat pipe, insulation as a second thermal resistor, and the cooling fins as a second cooling component.

The publication YAMAMOTO, Takuya; YOSHIWATARI, Shinichi; ICHIKAWA, Hiroaki. Expanded Lineup of High-Power 6th Generation IGBT Module Families. Fuji Electric Review, 2012, 58. Jg., No. 2, pp 60-64) indicates a specific embodiment of an IGBT module with a printed circuit board, the conductor track of which is connected to a load terminal of the semiconductor switch and to a first voltage potential.

### SUMMARY

The invention relates to switching devices for switching high voltages for cable testing by applying high voltage to a cable test sample and for discharging the cable test sample, wherein at least one device for switching a high voltage is connected to a negative high voltage source, and at least one identically embodied device for switching a high voltage is connected to a positive high voltage source. Said switching devices are distinguished in particular in that an increased voltage can be switched with a semiconductor switch. For this purpose, at least one electrically conductive heat sink having at least one printed circuit board with at least one semiconductor switch is arranged in an electrically insulated manner in a housing. The printed circuit board is a thermally conductive insulator between the semiconductor switch and the heat sink, to which and/or through which flows a coolant. A conductor is connected to a load terminal of the semiconductor switch and to a first voltage potential. Furthermore, an electrically conductive region of the housing is connected to a second voltage potential. Between the voltage potentials, a voltage divider is connected with an intermediate voltage potential connected to the heat sink.

### DETAILED DESCRIPTION

The underlying object of the invention specified in claim 1 is to increase the voltage that is switchable with a semiconductor switch coupled to the dissipatable power loss.

This object is solved by the features listed in claim 1.

The switching devices for switching high voltages for cable testing by applying a high voltage to a cable test sample and for discharging the cable test object, wherein at least one device for switching a high voltage is connected to a negative high voltage source, and at least one identically embodied device for switching a high voltage is connected to a positive high voltage source, are distinguished in particular in that an increased voltage is switchable with a semiconductor switch that also has a very high power loss that must be dissipated.

For this purpose, at least one electrically conductive heat sink with at least one printed circuit board with at least one semiconductor switch is arranged in an electrically insulated manner in an at least partially electrically conductive housing of the device for switching a high voltage. The printed circuit board is an insulator between the semiconductor switch and the heat sink. A conductor track of the printed circuit board is connected to a load terminal of the semiconductor switch and to a first voltage potential. Furthermore, the electrically conductive region of the housing is connected to a second voltage potential. A voltage divider is connected between the first voltage potential and the second voltage potential. In addition, an intermediate voltage potential of the voltage divider is connected to the heat sink.

The devices for switching a high voltage can in particular be used advantageously as switches in cable testing devices. They are characterised by the very high dissipatable power loss and thus by a significant increase in performance over switches, in which the high voltage is switched via a semiconductor switch that is insulated in a thermally conductive casting compound. The thermal conductivity of such casting compounds is lower than the thermal conductivity of a printed circuit board that is in particular a thermally conductive insulator between the semiconductor switch and the heat sink. As a result, longer cable runs can be tested with these devices for switching a high voltage. At the same time, the test time of a cable is reduced, which is particularly effective in the case of a three-phase test.

Here, the device for switching a high voltage comprises the discrete IGBTs as power loss generators, a ceramic circuit board as a thermal resistor, and a heat sink as a cooling component. The ceramic circuit board is a carrier with conductors for electrically connecting to all power electronic components in the form of the IGBTs, the associated protection components, and the associated control components as fittings of the circuit board. A coolant may flow to or through the heat sink.

Advantageous embodiments of the invention are given in the following embodiments.

According to one embodiment, the printed circuit board comprises a material having a high thermal conductivity, so that there is good heat conduction from the semiconductor switch to the heat sink. Thus there is significant dissipation of loss of power.

According to one embodiment, the housing has at least one flow channel of a coolant, wherein a region of the heat sink is a component of the flow channel. The flow medium in the flow channel may in particular be air or oil, so that there is forced convection.

According to one embodiment, the heat sink has at least one flow channel of a coolant. The flow medium in the flow channel may in particular be air or oil, so that there is forced convection.

According to one embodiment, the first voltage potential is the voltage potential of the high voltage source and the second voltage potential is a reference potential.

The reference potential according to one embodiment is the reference potential of the high voltage source and the housing in conjunction with the voltage divider.

According to one embodiment, the device is one component of a cascade with devices. The possibility of cascading allows the switching of different voltage series. In this case, a device can be used as a common part as a standard switch assembly in different devices of different nominal voltage.

According to one embodiment, the semiconductor switch has at least one insulated gate bipolar transistor (IGBT) or a thyristor.

According to one embodiment, the printed circuit board comprises a ceramic.

According to one embodiment, at least one device for switching a high voltage each is connected to at least one high voltage source. This permits desired voltage forms to be generated. The devices are used in particular to remove the lost heat from the semiconductor switches and the electrical insulation of the semiconductor switch at the high-voltage level.

One exemplary embodiment of the invention is depicted in each of the drawings and will be described in greater detail below.

### BRIEF DESCRIPTION OF THE DRAWINGS

In the drawings:

FIG. 1 depicts a device for switching a high voltage having semiconductor switches with a flow-through heat sink;

FIG. 2 depicts a device for switching a high voltage having semiconductor switches with a flow-through heat sink;

FIG. 3 depicts a device for switching a high voltage having semiconductor switches with a flow-through heat sink with a plurality of printed circuit boards; and,

FIG. 4 depicts a switching device for switching high voltages for cable testing by applying the high voltage to the cable test sample and discharging the cable test sample.

### DETAILED DESCRIPTION OF THE PREFERRED EMBODIMENTS

A device for switching a high voltage for connection to at least one high-voltage source 7 consists essentially of an electrically conductive heat sink 1, a printed circuit board 2, at least one semiconductor switch 3, a housing 4, and a voltage divider 5.

For this purpose, the electrically conductive heat sink 1 with the printed circuit board 2 with the semiconductor switch 3 are arranged in an electrically insulated manner in the electrically conductive housing 4. The printed circuit board 2 is an insulator between the semiconductor switch 3 and the heat sink 1. A conductor track 6 of the printed circuit board 2 is connected to a load terminal of the semiconductor switch 3 and to a first voltage potential P1. The electrically conductive housing 4 is connected to a second voltage potential P2. Switched between the first voltage potential P1 and the second voltage potential P2 is the voltage divider 5. It comprises at least of the resistors R1 and R2, which are connected in series. The intermediate voltage potential P3 is connected to the heat sink 1.

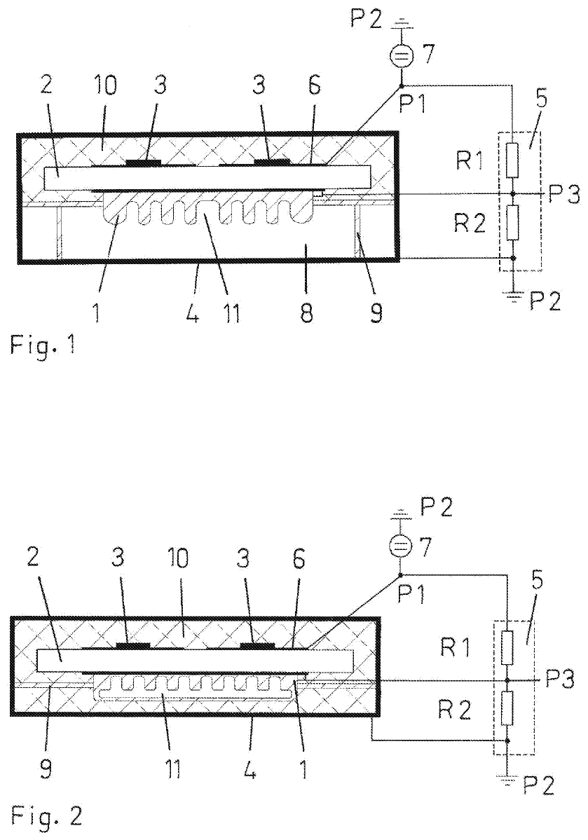

FIG. 1 depicts a device for switching a high voltage having semiconductor switches 3 with impinged heat sink 1 in a schematic representation.

In a first embodiment, the device for switching a high voltage is connected to at least one high voltage source 7. The heat sink 1 with the printed circuit board 2 is arranged at a distance from at least one wall of the housing 4 in the housing 4, so that a free space 8 and thus a flow channel 11 is formed. For this purpose, the heat sink 1 and/or the printed circuit board 2 is positioned in the housing 4 by means of at least one holder 9. The flow medium in the flow channel 11 may in particular be air, wherein there is a forced convection. The housing 4 has corresponding connections for the inlet and outlet of the air. The heat sink 1 disposed at intermediate voltage potential P3 is insulated by air from the housing 4 disposed on the second voltage potential P2. The printed circuit board 2 and the two semiconductor switches 3 shown in FIG. 1, for example, are insulated from the metal housing 4 with a casting compound 10. The thermal conductivity of the casting compound 10 plays a minor role, since most of the heat dissipates via the circuit board 2 made of a ceramic, the heat sink 1, and the flowing cooling medium.

FIG. 2 depicts a device for switching a high voltage having semiconductor switches 3 with a flow-through heat sink 1 in a schematic representation.

In a second embodiment, the device for switching a high voltage is connected to at least one high voltage source 7. The heat sink 1 with the printed circuit board 2 is arranged in the housing 4 at a distance from the walls of the housing 4. For this purpose, the heat sink 1 with the printed circuit board 2 is positioned with the holder 9 in the housing 4. The heat sink 1 has a flow channel 11 for a fluid medium. This may in particular be air, so that there is forced convection. The housing 4 and/or the heat sink 1 has corresponding connections for the inlet and outlet of the air. The heat sink 1 disposed on intermediate voltage potential P3, the printed circuit board 2, and the semiconductor switch 3 shown by way of example in FIG. 2 are insulated from the housing 4 disposed on the second voltage potential P2 by the casting compound 10. The thermal conductivity of the casting compound 10 plays a minor role, since most of the heat dissipates via the circuit board 2 made of a ceramic, the heat sink 1, and the flowing cooling medium.

FIG. 3 depicts a device for switching a high voltage having semiconductor switches 3 with a flow-through heat sink 1 with a plurality of printed circuit boards 2 in a schematic representation.

In a third embodiment, the device for switching a high voltage is connected to at least one high voltage source 7. The heat sink 1 of this embodiment has printed circuit boards 2 arranged on both sides, compared to the second embodiment. The heat sink 1 with the printed circuit boards 2 is disposed in the housing 4 spaced from the walls of the housing 4 by means of the holder 9. The heat sink 1 having the printed circuit boards 2 has a flow channel 11 with cooling ribs on both sides. The heat sink 1 disposed on intermediate potential P3, the printed circuit boards 2, and the semiconductor switches 3 are isolated from the housing 4 disposed on the second voltage potential P2 by the casting compound 10.

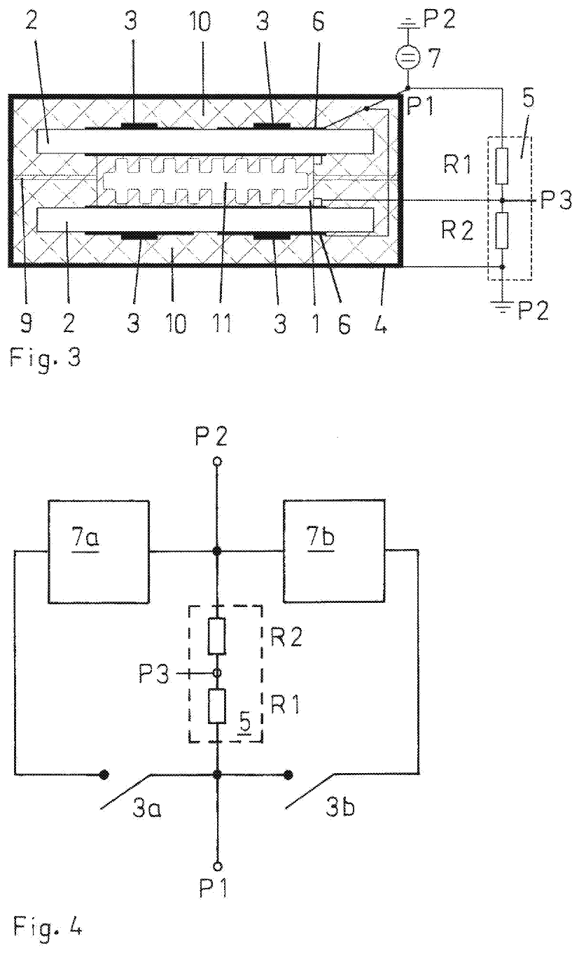

FIG. 4 depicts a schematic representation of a switching device for switching high voltages for cable testing by applying the high voltage to a cable test sample and discharging the cable test sample.

The devices for switching a high voltage for connecting to at least one high-voltage source 7 can be used in particular for generating a desired voltage form for cable testing for applying the voltage to and discharging the cable test object. For this purpose, at least two devices for switching a high voltage are connected to a negative high voltage source 7a and a positive high voltage source 7b. The devices are used in particular to remove the lost heat from the semiconductor switches 3a, 3b and the electrical insulation of the high-voltage level semiconductor switch 3a, 3b.

### LIST OF REFERENCE NUMERALS

1 Heat sink
2 Printed circuit board
3 Semiconductor switch
4 Housing
5 Voltage dividers
6 Conductor
7 High voltage source
8 Free space in the housing
9 Holders
10 Casting compound
11 Flow channel
P1 First voltage potential
P2 Second voltage potential
P3 Intermediate voltage potential
R1 Resistance
R2 Resistance

1. A switching device for switching high voltages for cable testing by applying high-voltage to a cable test sample and discharging the cable test sample, wherein at least one device for switching a high voltage is connected to a negative high voltage source (7a) and at least one identically embodied device for switching a high voltage is connected to a positive high voltage source (7b), characterised in that at least one electrically conductive heat sink (1) having at least one printed circuit board (2) with at least one semiconductor switch (3) is arranged in an electrically insulated manner in an at least partially electrically conductive housing (4) of the device for switching a high voltage, in that the printed circuit board (2) is an insulator between the semiconductor switch (3) and the heat sink (1), in that a conductor (6) of the printed circuit board (2) is connected to a load terminal of the semiconductor switch (3) and to a first voltage potential (P1) connected, in that the electrically conductive region of the housing (4) is connected to a second voltage potential (P2), in that a voltage divider (5) is switched between the first voltage potential (P1) and the second voltage potential (P2), and in that an intermediate voltage potential (P3) of the voltage divider (5) is connected to the heat sink (1).

2. The device according to claim 1, characterised in that the printed circuit board (2) comprises a material having a high thermal conductivity, so that there is good heat conduction from the semiconductor switch (3) to the heat sink (1).

3. The device according to claim 1, characterised in that the housing (4) has at least one flow channel (11) of a coolant, wherein a region of the heat sink (1) is a component of the flow channel (11).

4. The device according to claim 1, characterised in that the heat sink (1) has at least one flow channel (11) of a coolant.

5. The device according to claim 1, characterised in that the first voltage potential (P1) is the voltage potential of the high voltage source (7) and in that the second voltage potential (P2) is a reference potential.

6. The device according to claim 1, characterised in that the reference potential is the reference potential of the high voltage source (7) and of the housing (4) in conjunction with the voltage divider (5).

7. The device according to claim 1, characterised in that the device is one component of a cascade with devices.

8. The device according to claim 1, characterised in that the semiconductor switch (3) has at least one bipolar transistor with an insulated gate electrode or a thyristor.

9. The device according to claim 1, characterised in that the circuit board (2) comprises a ceramic.

10. The device according to claim 1, characterised in that at least one device for switching a high voltage is connected to at least one high voltage source (7).
